(19) United States
(12) Patent Application Publication
(10) Pub. No.: US 2010/0307686 A1
(43) Pub. Date: Dec. 9, 2010

(54) SUBSTRATE PROCESSING APPARATUS

(75) Inventors: Hachishiro Iizuka, Nirasaki (JP); Yuki Mochizuki, Nirasaki (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/793,859

(22) Filed: Jun. 4, 2010

Related U.S. Application Data
(60) Provisional application No. 61/222,816, filed on Jul. 2, 2009.

(30) Foreign Application Priority Data
Jun. 5, 2009 (JP) 2009-136268

(51) Int. Cl. C23F 1/08; C23C 16/44

(52) U.S. Cl. 156/345.34; 118/724

(57) ABSTRACT

Provided is a substrate processing apparatus capable of effectively heating each component without generating an abnormal electric discharge. The substrate processing apparatus 10 includes: a depressurizable processing chamber 11; a susceptor 12 provided within the processing chamber 11; a shower head 27 provided at a ceiling portion of the processing chamber 11 so as to face the susceptor 12; a focus ring 24 provided at an outer peripheral portion of a top surface of the susceptor 12; and a ring-shaped infrared radiant heater 26 provided in a vicinity of the focus ring 24. The heater 26 includes an infrared radiator 26a and a quartz ring 26b for sealing the infrared radiator 26a therein.

### CROSS-REFERENCE TO RELATED APPLICATION

This application claims the benefit of Japanese Patent Application No. 2009-136268 filed on Jun. 5, 2009, and U.S. Provisional Application Ser. No. 61/222,816 filed on Jul. 2, 2009, the entire disclosures of which are incorporated herein by reference.

### FIELD OF THE INVENTION

The present disclosure relates to a substrate processing apparatus, and, in particular, relates to a substrate processing apparatus configured to remove substrate processing hindrance factors by a heater provided within a processing chamber.

### BACKGROUND OF THE INVENTION

A substrate processing apparatus includes, for example, a semiconductor manufacturing apparatus, a vacuum processing apparatus, and a film forming apparatus. Further, a plasma processing apparatus has been widely known as a substrate processing apparatus for processing a substrate by plasma. The plasma processing apparatus includes a depressurizable processing chamber in which plasma is generated, and a substrate mounting table (susceptor) for mounting thereon a wafer as a substrate is provided in the processing chamber. The susceptor includes a circular plate-shaped electrostatic chuck (ESC) positioned on a top surface of the susceptor, and a focus ring which is made of, e.g., silicon and positioned at an outer peripheral portion of a top surface of the electrostatic chuck.

In the plasma processing apparatus, prior to starting a process, there is performed an exhaust process for exhausting a gas within the chamber. That is, there has been known that an etching rate distribution on the wafer can be uniformized by previously removing substrate processing hindrance factors such as reaction products or water adsorbed on an inner wall surface or on other components in the chamber, and, thus, processing uniformity in the wafer surface can be improved. Typically, there has been known a way in which water is heated and evaporated, and the water vapor is removed by evacuation. However, for example, if a metal resistance heater is provided within the chamber in order to heat water or the like, the metal is exposed in the chamber, which may cause an abnormal electric discharge.

Therefore, there has been suggested a substrate processing apparatus including a heat transfer heater embedded in a susceptor so as to control a temperature of a focus ring and its adjacent members (see, for example, Patent Document 1).

Patent Document 1: Japanese Laid-open Publication No.

However, a substrate processing apparatus has a configuration combined with a plurality of components, and gaps between the respective components serve as heat insulating vacuum layers, and, thus, a heat conductivity becomes low. Accordingly, in a conventional substrate processing apparatus employing an embedded heater, respective components, particularly, a focus ring and its adjacent members may not be effectively heated.

### BRIEF SUMMARY OF THE INVENTION

In view of the foregoing, the present disclosure provides a substrate processing apparatus capable of effectively heating each component without generating an abnormal electric discharge.

In accordance with one aspect of the present disclosure, there is provided a substrate processing apparatus including a depressurizable processing chamber; a substrate mounting table provided within the processing chamber; a shower head provided at a ceiling portion of the processing chamber so as to face the substrate mounting table; and a focus ring provided at an outer peripheral portion of a top surface of the substrate mounting table. Further, the substrate processing apparatus includes a ring-shaped infrared radiant heater provided in a vicinity of the focus ring and the heater includes an infrared radiator and a glass body for sealing the infrared radiator therein.

Further, in the substrate processing apparatus, there may be no infrared radiation block member between the focus ring and the heater.

In the substrate processing apparatus, the focus ring and the heater may be directly adjacent to each other.

In the substrate processing apparatus, the heater may be connected with an external power supply via a power supply line penetrating the substrate mounting table.

In the substrate processing apparatus, the heater may be provided at an outer peripheral portion of the focus ring so as to surround the focus ring with a space therebetween.

In the substrate processing apparatus, the heater may be connected with an external power supply via a power supply line penetrating a sidewall of the processing chamber.

In the substrate processing apparatus, the processing chamber may include an exhaust plate dividing a space between the substrate mounting table and the shower head and an exhaust space below the substrate mounting table, and the heater may be connected with an external power supply via a power supply line penetrating the exhaust plate.

In the substrate processing apparatus, the heater may be provided to be movable in a vertical direction along an inner wall surface of the processing chamber.

In the substrate processing apparatus, a portion, facing a member which need not be heated, on a surface of the glass body of the heater may be coated with an infrared reflection film.

In the substrate processing apparatus, the infrared radiator may include a bundle of carbon wires.

In the substrate processing apparatus, the infrared radiator may have an emission peak in a wavelength of about 1200 nm.

The substrate processing apparatus includes the ring-shaped infrared radiant heater provided in the vicinity of the focus ring and the heater includes the infrared radiator and the glass body for sealing the infrared radiator therein.

Therefore, the infrared radiator is not exposed within the processing chamber and is insulated. As a result, even if the heater is provided within the processing chamber, an abnormal electric discharge may not be generated. Further, since the heater radiates infrared rays, components such as the focus ring may be effectively heated.

Further, in the substrate processing apparatus, there may be no infrared radiation block member between the focus ring and the heater. Therefore, even if the focus ring is distanced away from the heater, the focus ring may be effectively heated by the infrared radiation.

In the substrate processing apparatus, the focus ring and the heater may be directly adjacent to each other. Therefore, the focus ring can be heated not only by the infrared radiation but also by a direct heat transfer.

Accordingly, the focus ring and its adjacent members may be more effectively heated.

In the substrate processing apparatus, the heater may be connected with the external power supply via the power supply line penetrating the substrate mounting table. Therefore, a problem caused by exposure of the power supply line within the processing chamber can be solved.

In the substrate processing apparatus, the heater may be provided at the outer peripheral portion of the focus ring so as to surround the focus ring with a space therebetween. Therefore, the focus ring and its adjacent member may be indirectly heated effectively by the infrared radiation. Further, the abnormal electric discharge hardly occurs.

In the substrate processing apparatus, the heater may be connected with the external power supply via the power supply line penetrating the sidewall of the processing chamber. Therefore, the length of the power supply line can be as short as possible within the processing chamber.

In the substrate processing apparatus, the processing chamber may include the exhaust plate dividing the space between the substrate mounting table and the shower head and the exhaust space below the substrate mounting table, and the heater may be connected with the external power supply via the power supply line penetrating the exhaust plate. Therefore, a problem caused by providing the power supply line within the processing chamber may be suppressed.

In the substrate processing apparatus, the heater may be provided to be movable in a vertical direction along an inner wall surface of the processing chamber. Therefore, a portion to be heated within the processing chamber may be indirectly heated by the infrared radiation while moving the heater if necessary.

In the substrate processing apparatus, the portion, facing the member which need not be heated, on a surface of the glass body of the heater may be coated with the infrared reflection film. Therefore, even if the member, which need not be heated, is placed to face the portion, the member may not be heated by the infrared radiation.

In the substrate processing apparatus, the infrared radiator may include the bundle of carbon wires. Therefore, metal may not be used as a material of the heater, and, thus, the abnormal electric discharge may be suppressed.

In the substrate processing apparatus, the infrared radiator may have the emission peak in the wavelength of about 1200 nm. Therefore, the respective components may be effectively heated by the infrared radiation at a specified wavelength.

### BRIEF DESCRIPTION OF THE DRAWINGS

The disclosure may best be understood by reference to the following description taken in conjunction with the following figures:

FIG. 1 is a schematic cross-sectional view of a substrate processing apparatus in accordance with a first embodiment of the present invention;

FIG. 2 is an enlarged view of main parts of FIG. 1;

FIG. 3 shows a spectral distribution of an emission spectrum of a heater;

FIGS. 4A and 4B are explanatory diagrams showing a shape of a heater, and FIG. 4A is a schematic diagram showing its external appearance, and FIG. 4B is a cross-sectional view taken along line B-B;

FIG. 5 shows a relationship between a current A supplied to a 30 A-type test heater and an elapsed time h and a reaching temperature ° C.;

FIGS. 6A and 6B show a relationship between an exhaust time of a gas in a chamber 11 at the room temperature (25° C.) and a partial pressure in the chamber, and FIG. 6A shows a case of evacuation by a turbo molecular pump (TMP), and FIG. 6B shows a case of evacuation by a TMP and a Cryopump;

FIG. 7 is a schematic cross-sectional view of a configuration of main parts of a substrate processing apparatus in accordance with a second embodiment of the present invention; and

FIG. 8 is a schematic cross-sectional view of a configuration of main parts of a substrate processing apparatus in accordance with a third embodiment of the present invention.

### DETAILED DESCRIPTION OF THE INVENTION

Hereinafter, there will be explained a first embodiment of the present invention with reference to the drawings.

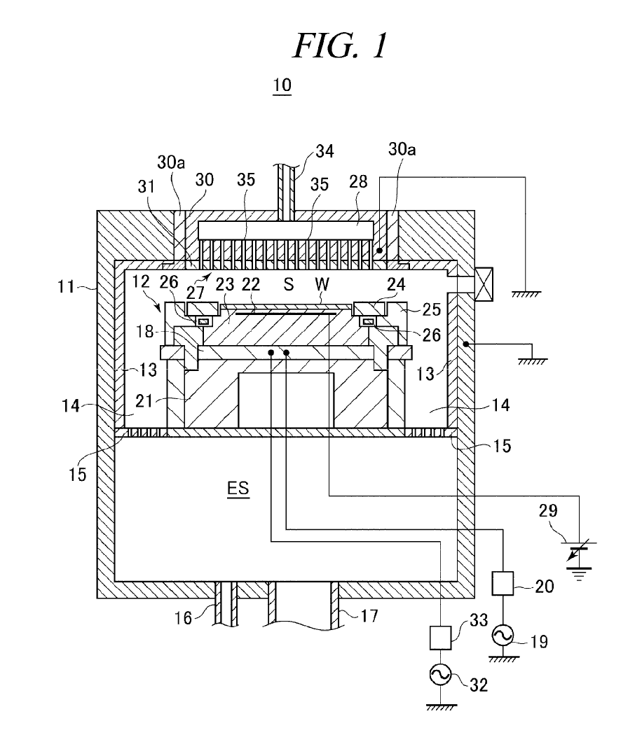

FIG. 1 is a schematic cross-sectional view of a substrate processing apparatus in accordance with a first embodiment of the present invention. The substrate processing apparatus is configured to perform a reactive ion etching (RIE) process on a semiconductor wafer W as a substrate.

A substrate processing apparatus 10 in FIG. 1 has a cylindrical processing chamber 11 including a processing space S in its upper part. Plasma, which will be described later, is generated in the processing space S. Further, provided within the processing chamber 11 is a cylindrical susceptor 12 as a substrate mounting table for mounting thereon a semiconductor wafer W (hereinafter, simply referred to as “wafer W”) having a diameter of, e.g., about 300 mm. An inner wall surface of the processing chamber 11 is covered with a sidewall member 13 made of an insulating material.

In the substrate processing apparatus 10, a gas exhaust path 14 serving as a flow path for exhausting a gas above the susceptor 12 to the outside of the processing chamber 11 is provided between the inner wall surface of the processing chamber 11 and a side surface of the susceptor 12. Provided at the gas exhaust path 14 is a plate-shaped exhaust plate 15 having a plurality of vent holes. The exhaust plate 15 divides the gas exhaust path 14 and a lower space of the processing chamber 11, i.e., an exhaust space ES. Further, a rough exhaust pipe 16 and a main exhaust pipe 17 are opened from the exhaust space ES. The rough exhaust pipe 16 is connected with a dry pump (DP) (not shown) and the main exhaust pipe 17 is connected with a turbo molecular pump (TMP) (not shown).

The rough exhaust pipe 16, the main exhaust pipe 17, the DP, and the TMP constitute an exhaust device. Further, this exhaust device is configured to exhaust a gas within the processing space S to the outside of the processing chamber 11 through the gas exhaust path 14 and the exhaust space ES, thereby depressurizing the processing space S to a high-vacuum state.

The susceptor 12 includes therein a high-frequency power plate 18 made of a conductive material such as aluminum, and this high-frequency power plate 18 is connected with a first high-frequency power supply 19 via a first matcher 20. The first high-frequency power supply 19 is configured to apply a first high-frequency power to the high-frequency power plate 18. The first matcher 20 is configured to maximize a supply efficiency of the first high-frequency power to the high-frequency power plate 18 by reducing reflection of the high-frequency power from the high-frequency power plate 18. Further, the high-frequency power plate 18 is connected with a second high-frequency power supply 32 via a second matcher 33, and the second high-frequency power supply 32 is configured to apply a second high-frequency power having a different frequency from a frequency of the first high-frequency power to the high-frequency power plate 18. Furthermore, the second matcher 33 provides the same function as the first matcher 20. Accordingly, the susceptor 12 serves as a lower high-frequency electrode and applies the first and second high-frequency powers to the processing space S. Moreover, in the susceptor 12, a support 21 made of an insulating material such as alumina (Al₂O₃) is provided beneath the high-frequency power plate 18.

In the susceptor 12, an electrostatic chuck 23 is provided on the high-frequency power plate 18. The electrostatic chuck 23 includes therein an electrode plate 22 electrically connected with a DC power supply 29. When the wafer W is mounted on the susceptor 12, the wafer W is mounted on the electrostatic chuck 23. The wafer W is attracted to and held on the electrostatic chuck 23 by Coulomb force or Johnson-Rahbek force caused by a DC voltage applied to the electrode plate 22.

On the susceptor 12, a ring-shaped focus ring 24 is mounted so as to surround a peripheral portion of the wafer W attracted to and held on a top surface of the susceptor 12. The focus ring 24 is made of silicon (Si), silica (SiO₂), or silicon carbide (SiC). Further, the focus ring 24 exposed to the processing space S is configured to focus the plasma in the processing space S toward the surface of the wafer W, thereby improving an efficiency of the RIE process. Further, a ring-shaped cover ring 25 made of quartz is positioned around the focus ring 24 so as to protect a side surface of the focus ring 24.

Provided beneath the focus ring 24 is a ring-shaped infrared radiant heater (hereinafter, referred to as “lamp heater”) 26. The lamp heater 26 is configured such that an infrared radiator including a bundle of carbon wires is sealed in a glass body. A configuration/operation of the lamp heater 26 will be described later.

On the top surface of the susceptor 12, a plurality of heat transfer gas supply holes (not shown) is formed at a portion where the wafer W is attracted and held. Through the plurality of heat transfer gas supply holes, a helium (He) gas as a heat transfer gas is supplied to a gap between the susceptor 12 and a rear surface of the wafer W, thereby improving a heat transfer efficiency between the wafer W and the susceptor 12.

At a ceiling portion of the processing chamber 11, a shower head 27 for introducing a gas is provided so as to face the susceptor 12. The shower head 27 includes an electrode plate support 30 in which a buffer room 28 is provided and an upper electrode plate 31 held by the electrode plate support 30. The upper electrode plate 31 is a circular plate-shaped member made of a conductive material such as silicon. The electrode plate support 30 is also made of a conductive material. Further, between the ceiling portion of the processing chamber 11 and the electrode plate support 30, an insulating ring 30a made of an insulating material is provided. The insulating ring 30a is configured to insulate the electrode plate support 30 from the ceiling portion of the processing chamber 11. Furthermore, the electrode plate support 30 is grounded.

The buffer room 28 of the shower head 27 is connected with a processing gas supply unit (not shown) via a processing gas introduction line 34. Further, the shower head 27 includes a plurality of gas holes 35 connecting the buffer room 28 with the processing space S. A processing gas supplied to the buffer room 28 through the processing gas introduction line 34 is supplied to the processing space S via the gas holes 35 of the shower head 27.

Within the processing chamber 11 of the substrate processing apparatus 10, the susceptor 12 is configured to apply the first and second high-frequency powers to the processing space S between the susceptor 12 and the upper electrode plate 31 as described above. Thus, the processing gas supplied through the shower head 27 is excited into high density plasma, so that positive ions or radicals in the processing space S are generated, and the RIE process is performed onto the wafer W by the generated positive ions or radicals.

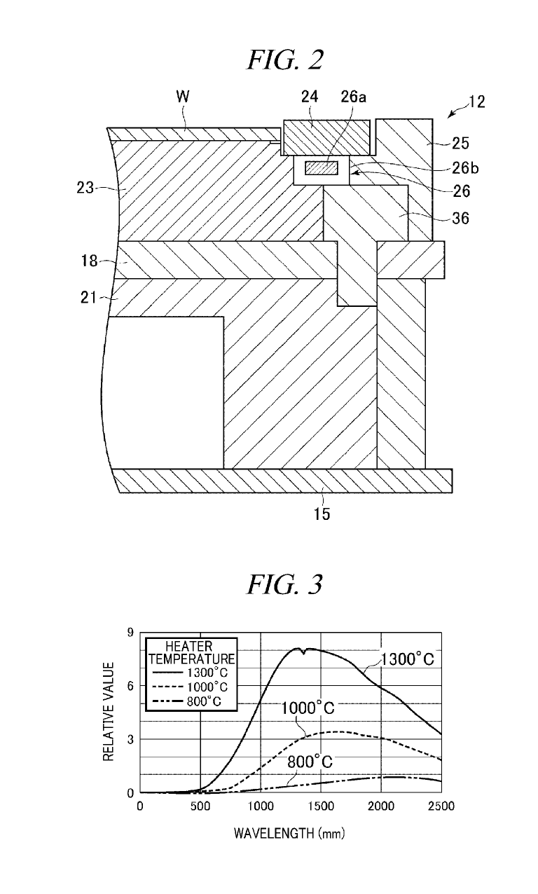

FIG. 2 is an enlarged view of main parts of FIG. 1.

As depicted in FIG. 2, a peripheral portion of the wafer W mounted on the susceptor 12 faces an inner peripheral portion of the focus ring 24, and the bottom surface of the focus ring 24 is in contact with the top surface of the lamp heater 26. Further, the lamp heater 26 is in contact with the electrostatic chuck 23 and the quartz cover ring 25 respectively positioned on the left and right sides of the lamp heater 26 and the quartz insulating ring 36 positioned beneath the lamp heater 26. Thus, the lamp heater 26 is configured to directly heat these components by heat transfer. Furthermore, the lamp heater 26 is configured to indirectly heat adjacent components by a radiant heat propagating through the members made of quartz or glass.

Here, for example, an ES ring HT of Covalent Materials Corporation can be suitably used as a lamp heater 26. The ES ring HT (hereinafter, referred to as “lamp heater”) is an infrared emitting heater and typically has an emission peak in a wavelength of about 1200 nm.

FIG. 3 is a view showing a spectral distribution of an emission spectrum of the lamp heater 26. In FIG. 3, the lamp heater 26 has an emission peak in the wavelength of about 1200 nm and such a peak can be apparently seen when a temperature of the heater is equal to or higher than about 1000° C.

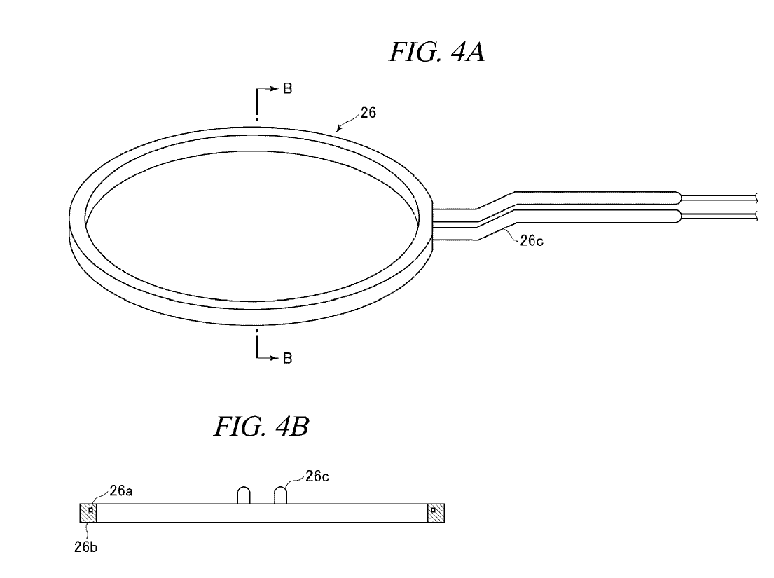

FIGS. 4A and 4B are explanatory diagrams showing a shape of the lamp heater 26, and FIG. 4A is a schematic diagram showing its external appearance, and FIG. 4B is a cross-sectional view taken along line B-B of FIG. 4A. In FIG. 4A, the lamp heater 26 has a ring shape which is substantially same as that of the focus ring 24, and the lamp heater 26 mainly has an infrared radiator 26a including a bundle of ring-shaped carbon wires and a quartz ring 26b sealing therein the infrared radiator 26a (see FIG. 4B). Further, the lamp heater 26 includes a power supply line 26c connecting the infrared radiator 26a with an external power supply (not shown). For example, the infrared radiator 26a includes about ten bundles of carbon wires and each bundle has about 3000 carbon wires and each carbon wire has about 7 μm/P. Further, the quartz ring 26b has a surface hardly absorbing a radiant heat.

A cross section of the infrared radiator 26a is formed in, e.g., a rectangular shape as depicted in FIG. 4B, and desirably, a cross section of the quartz ring 26b may also be of a rectangular shape. With this configuration, the lamp heater 26 can be in surface contact with their adjacent members including the focus ring 24. Thus, heat transfer through a contact surface as well as heat radiation becomes available. The power supply line 26c connects the infrared radiator 26a with the external power supply (not illustrated) by penetrating the electrostatic chuck 23 constituting the substrate mounting table, for example. Further, shapes of the cross sections of the infrared radiator 26a and the quartz ring 26b of the lamp heater 26 are not limited to the rectangular shape and may be formed in, e.g., a circular shape.

The lamp heater 26 is configured to indirectly heat a heating target member mainly by radiant heating. For example, the lamp heater 26 can be configured to heat a surface of the member about 200 mm away therefrom to a temperature of about 700° C. A temperature increasing time of the lamp heater 26 is shorter than a temperature increasing time of a typical metal resistance heater. For example, if currents of about 7 A to about 16 A are supplied to a 30 A-type heater for testing step by step, the heater reaches a preset temperature in a short time every step, and then stably maintains a reaching temperature in each step.

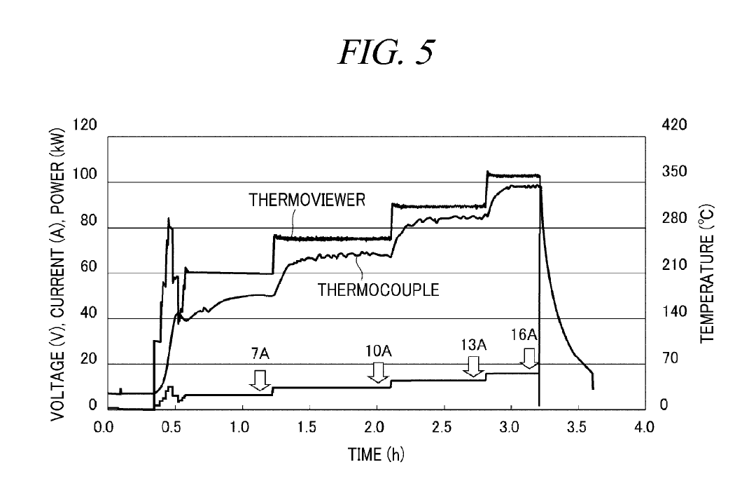

FIG. 5 is a view showing a relationship between a current A supplied to a 30 A-type heater for testing and an elapsed time h and a reaching temperature C. In FIG. 5, a temperature of the lamp heater is measured by a thermoviewer. To be specific, there are current/voltage values and temperatures measured by the thermoviewer when a temperature measured by a thermocouple inserted into the infrared radiator 26a becomes stable.

In FIG. 5, currents of about 7 A, 10 A, 13 A, and 16 A are supplied while varying its values. If a current of about 7 A is supplied for about 15 minutes, a temperature of the heater is stable at about 210° C. Thereafter, upon increasing a current to about 10 A, 13 A, and 16 A in sequence, a temperature of the heater is immediately increased to about 260° C., 320° C., and 360° C., respectively, and then the respective temperatures are stably maintained. Accordingly, it can be seen that the lamp heater 26 has an excellent control responsiveness. Further, the temperatures measured by the thermoviewer are analogous to the temperatures measured by the thermocouple, and, thus, it can be seen that the measured values by thermoviewer are reliable.

The lamp heater 26 is economically advantageous in that it consumes less power as compared to a metal resistance heater or the like. Further, since the lamp heater 26 primarily provides radiant heating, it does not have such a problem that a lamp, e.g., a halogen lamp, is dimmed by water adsorbed on a surface thereof and heat generation of the lamp is suppressed.

Hereinafter, an operation of the substrate processing apparatus of FIG. 1 including the lamp heater 26 will be explained.

In the substrate processing apparatus of FIG. 1, before the wafer W to be processed was loaded into the chamber 11, electric power was applied to the lamp heater 26 so as to heat the focus ring 24 and its adjacent members to a temperature of about 200° C. and inside of the chamber 11 was exhausted. In only about one hour after starting the exhaust process, water in the chamber 11 was almost completely desorbed and exhausted.

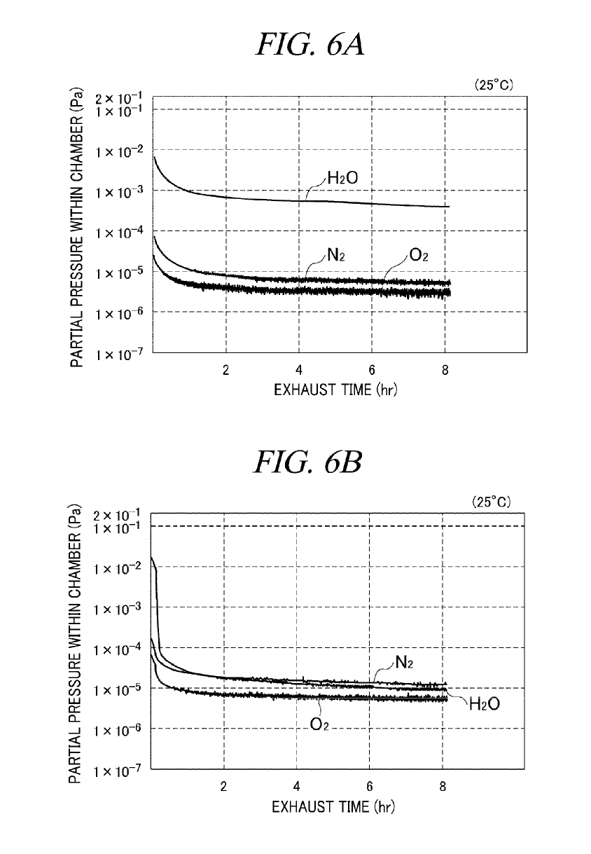

FIGS. 6A and 6B show a relationship between an exhaust time of a gas in the chamber 11 at the room temperature (25° C.) and a partial pressure in the chamber. FIG. 6A shows a case of evacuation by a main pump (TMP), and FIG. 6B shows a case of evacuation by a main pump (TMP) and a Cryopump (about 110K to about 140K). In FIG. 6A, a partial pressure of water regarded to have a bad influence on a plasma process is lowered to about 1×10⁻³ Pa in only about one hour after starting an evacuating process. However, as can be seen from FIG. 6B, when the Cryopump is additionally used thereto, a partial pressure of water within the chamber 11 is much lowered to about 1×10⁻⁴ Pa or less. Therefore, it can be seen that when the Cryopump is not used, water is not sufficiently desorbed from the components nor evacuated to the outside of the chamber 11. Further, although an additional use of the Cryopump is effective, if the evacuating process is stopped, a partial pressure of water within the chamber 11 becomes close to a state as shown in FIG. 6A by water adsorbed on surfaces of the components. According to this result, it is deemed that in order to effectively lower the partial pressure of water within the chamber 11, a discharge of water needs to be accelerated by heating surfaces of the components to a temperature equal to or higher than a boiling point of water as performed in the present embodiment.

After water within the chamber 11 was evacuated, a pressure within the chamber 11 was set to, e.g., about 1×10 Pa (75 mTorr) and the wafer W to be processed was loaded into the chamber 11 and mounted on the susceptor 12. Thereafter, for example, a CF-based or CH-based gas as a processing gas was supplied from the shower head 27 into the chamber 11 at a flow rate ranging from about 10 sccm to about 100 sccm, and an Ar gas and an O₂ gas were supplied from the shower head 27 into the chamber 11 at a flow rate ranging from about 200 sccm to about 1000 sccm. Further, an excitation power of about 200 W to about 500 W and a bias power of about 2000 W to about 4000 W were applied to the high-frequency power plate 18 of the susceptor 12, and a DC voltage of about −300 V to about 0 V was applied to the shower head 27. Here, the processing gas was excited into plasma by the high-frequency power applied to the processing space S, so that ions or radicals were generated. A plasma process was performed onto the wafer W by these ions or radicals.

In accordance with the present embodiment, since the ring-shaped infrared radiant lamp heater 26 is provided in the vicinity of the focus ring 24, e.g., beneath the focus ring 24, it is possible to effectively heat the components within the chamber including the focus ring by heat transfer or radiation. Accordingly, temperatures of the components including the focus ring become stable, and, thus, the plasma process can be stably performed. Further, even if there is a gap between the lamp heater 26 and each component, if each component is in the range of the infrared radiation, the lamp heater 26 can heat each component. Therefore, a heat transfer sheet which has been conventionally used between each component is not needed any longer. Furthermore, since the lamp heater does not include any metal member, even if the lamp heater is provided in the chamber 11, the lamp heater does not cause an abnormal electric discharge.

In accordance with the present embodiment, the cross section of the lamp heater 26 is formed in a rectangular shape, and, thus, a contact surface with its adjacent components including the focus ring 24 is a planar surface. Therefore, in addition to infrared radiant heating, each component may be heated by heat transfer via the contact surface, so that heating efficiency can be improved.

In accordance with the present embodiment, each component within the chamber 11 may be effectively heated, and, thus, during the exhaust process prior to starting the plasma process, the partial pressure of water can be reduced as low as possible. Conventionally, several tens to several hundreds of dummy wafers have been required to decrease a partial pressure of water to a desired level or less. However, in accordance with the present embodiment, the number of dummy wafers can be reduced to about several to several tens. Further, most of the components in the chamber 11 are consumables made of, e.g., glass, so that the components need to be replaced with new ones. Accordingly, water adsorbed on the new one may be introduced into the chamber 11. However, by performing the heating and exhaust processes in advance prior to starting the plasma process, not only the existing water within the chamber 11 but also water adsorbed on the replaced new one and introduced into the chamber 11 can be evacuated to outside of the chamber 11 in a relatively short time. Therefore, the plasma process after the heating and exhaust processes can be stably performed.

In the present embodiment, the lamp heater 26 is connected with the external power supply via the power supply line 26c penetrating the electrostatic chuck 23 of the substrate mounting table 12. With this configuration, a problem caused by exposure of the power supply line 26c within the processing chamber 11 can be solved.

Hereinafter, a second embodiment of the present invention will be explained.

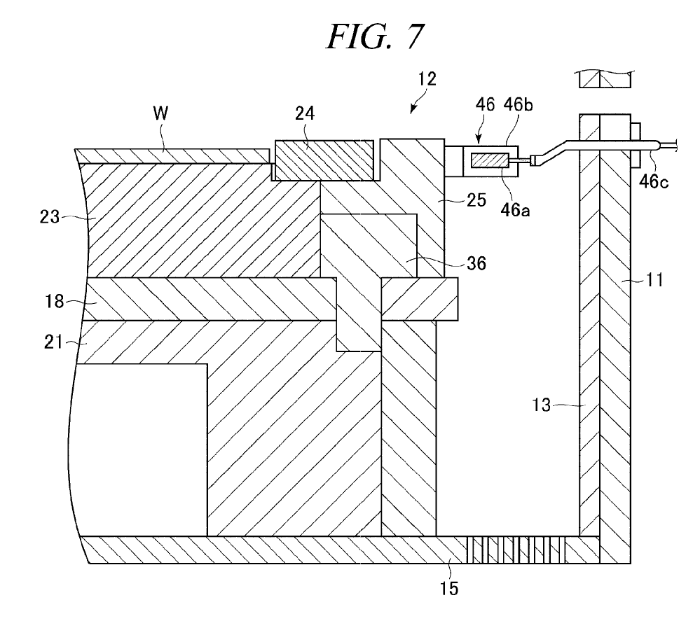

FIG. 7 is a schematic cross-sectional view of a configuration of a substrate processing apparatus in accordance with a second embodiment of the present invention.

In FIG. 7, the same components as those of the substrate processing apparatus of FIG. 1 operate in the same manner, and, thus, they will be assigned same reference numerals and descriptions thereof will be omitted. This substrate processing apparatus is different from the substrate processing apparatus of FIG. 1 in that instead of the lamp heater 26, a lamp heater 46 is provided so as to surround the focus ring 24 of the susceptor 12 with a predetermined space therebetween.

The lamp heater 46 is connected with an external power supply (not shown) via a power supply line 46c penetrating the sidewall of the processing chamber 11. Here, the power supply line 46c may be connected with the external power supply via a service port of the chamber 11. Further, by installing a bellows outside the penetrating portion of the power supply line 46c at the sidewall of the chamber 11, a difference in a thermal expansion between the sidewall of the chamber 11 and the power supply line 46c may be absorbed. Alternatively, the power supply line 46c may be extended downwardly so as to penetrate the exhaust plate 15 and may connect a heating element 46a with the external power supply. Therefore, problems caused by the power supply line 46c provided within the processing chamber 11 can be suppressed.

In accordance with the present embodiment, since the ring-shaped lamp heater 46 is provided at an outer peripheral portion of the focus ring 24 so as to surround the focus ring 24 with a space therebetween, the lamp heater 46 can be configured to indirectly heat the focus ring 24 and its adjacent members effectively. Therefore, the focus ring 24, its adjacent members, and an inner wall surface of the chamber 11 can be stably heated, and, thus, the plasma density becomes stable and uniformity in the substrate surface becomes improved.

Further, in accordance with the present embodiment, since the lamp heater 46 is employed within the chamber 11, it is possible to reduce time required for an exhaust process to evaporate, desorb, and evacuate substrate processing hindrance factors such as water and reaction products by previously heating the inside of the chamber 11 by the lamp heater 46 prior to starting the plasma process. Therefore, the number of required dummy wafers can be reduced as small as possible. Further, since the infrared radiator 46a of the lamp heater 46 includes a bundle of carbon wires and covered with a quartz glass body 46b, an abnormal electric discharge caused by a metal member exposed within the chamber 11 hardly occurs.

Since the substrate processing apparatus has a configuration combined with a plurality of components, a space between the respective components may serve as a heat insulating vacuum space. However, in accordance with the present embodiment, the lamp heater 46 can be configured to indirectly heat even the components distanced away from the lamp heater 46 by the infrared radiation. Therefore, the inside of the chamber 11 may be effectively heated and a substrate processing can be performed stably.

Furthermore, in accordance with the present embodiment, the lamp heater 46 is connected with the external power supply via the power supply line 46c penetrating the sidewall of the processing chamber 11. Therefore, the length of the power supply line within the processing chamber can be as short as possible.

In the present embodiment, the surface of the glass body 46b of the lamp heater 46 facing the members, which need not be heated by the infrared radiation, such as the substrate and the substrate mounting table, can be coated with an infrared reflection film so as to avoid being heated. As the infrared reflection film, for example, a hot mirror, a cold mirror, and a half mirror of Opto-line Corporation can be used. For example, light passes through these infrared reflection films, but heat is blocked by these infrared reflection films. Therefore, the infrared reflection film does not have a bad influence on a plasma process.

In the present embodiment, the lamp heater 46 is supported by a non-illustrated support member such as a quartz column, and fixed to an exhaust baffle plate or the chamber.

Hereinafter, a third embodiment of the present invention will be explained.

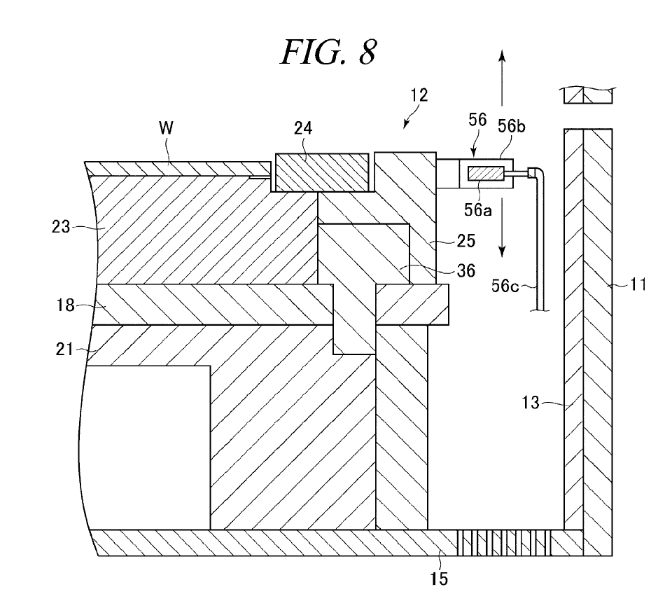

FIG. 8 is a schematic cross-sectional view of a configuration of a substrate processing apparatus in accordance with the third embodiment of the present invention. In FIG. 8, the same components as those of the substrate processing apparatuses of FIGS. 1 and 7 operate in the same manner, and, thus, they will be assigned same reference numerals and descriptions thereof will be omitted. This substrate processing apparatus is different from the substrate processing apparatus of FIG. 7 in that instead of the lamp heater 46, a lamp heater 56 is provided so as to be movable in a vertical direction along the sidewall of the chamber 11.

As shown in FIG. 8, the lamp heater 56 is connected with an external power supply (not illustrated) via a power supply line 56c penetrating the exhaust plate 15 configured to divide the processing space S and the exhaust space ES. Further, desirably, a bellows (not shown) for absorbing a vertical movement of the power supply line 56c may be provided outside the chamber 11.

In accordance with the present embodiment, the lamp heater 56 is provided so as to be movable in the vertical direction along the sidewall of the chamber 11. Therefore, during a plasma process performed onto the wafer W, the lamp heater 56 may be fixed in the vicinity of the focus ring 24 so as to heat the focus ring 24 and its adjacent members, so that process stability is secured. After the process, for example, the lamp heater 56 may be moved downwardly to be in a standby state. Further, during the exhaust process, the lamp heater 56 may be moved vertically between a vicinity of the shower head 27 and the exhaust plate 15 so that the inside of the chamber 11 can be uniformly heated and the substrate process hindrance factors can be effectively removed.

In the present embodiment, as a supporting and elevating mechanism for the lamp heater 56, for example, a well-known substrate transfer elevator (wafer lifter) may be used. Typically, a driving unit of the elevator may be provided outside the chamber 11.

In the second and third embodiments, the lamp heater 26 of the first embodiment may be additionally used. If so, it is possible to effectively heat the inside of the chamber 11 by a synergy effect of the lamp heaters.

In the above-described embodiments, the substrate to be plasma-processed is not limited to a wafer for a semiconductor device but can be any one of various kinds of substrates used for a flat panel display (FPD) including a liquid crystal display (LCD), a photo mask, a CD substrate, a print substrate, or the like.

What is claimed is:

1. A substrate processing apparatus including a depressurizable processing chamber, a substrate mounting table provided within the processing chamber, a shower head provided at a ceiling portion of the processing chamber so as to face the substrate mounting table, and a focus ring provided at an outer peripheral portion of a top surface of the substrate mounting table, the substrate processing apparatus comprising:
a ring-shaped infrared radiant heater provided in a vicinity of the focus ring, the heater including an infrared radiator and a glass body for sealing the infrared radiator therein.

2. The substrate processing apparatus of claim 1, wherein there is no infrared radiation block member between the focus ring and the heater.

3. The substrate processing apparatus of claim 1, wherein the focus ring and the heater are directly adjacent to each other.

4. The substrate processing apparatus of claim 2, wherein the focus ring and the heater are directly adjacent to each other.

5. The substrate processing apparatus of claim 1, wherein the heater is connected with an external power supply via a power supply line penetrating the substrate mounting table.

6. The substrate processing apparatus of claim 2, wherein the heater is connected with an external power supply via a power supply line penetrating the substrate mounting table.

7. The substrate processing apparatus of claim 3, wherein the heater is connected with an external power supply via a power supply line penetrating the substrate mounting table.

8. The substrate processing apparatus of claim 4, wherein the heater is connected with an external power supply via a power supply line penetrating the substrate mounting table.

9. The substrate processing apparatus of claim 1, wherein the heater is provided at an outer peripheral portion of the focus ring so as to surround the focus ring with a space therebetween.

10. The substrate processing apparatus of claim 2, wherein the heater is provided at an outer peripheral portion of the focus ring so as to surround the focus ring with a space therebetween.

11. The substrate processing apparatus of claim 9, wherein the heater is connected with an external power supply via a power supply line penetrating a sidewall of the processing chamber.

12. The substrate processing apparatus of claim 10, wherein the heater is connected with an external power supply via a power supply line penetrating a sidewall of the processing chamber.

13. The substrate processing apparatus of claim 9, wherein the processing chamber includes an exhaust plate dividing a space between the substrate mounting table and the shower head and an exhaust space below the substrate mounting table, and the heater is connected with an external power supply via a power supply line penetrating the exhaust plate.

14. The substrate processing apparatus of claim 10, wherein the processing chamber includes an exhaust plate dividing a space between the substrate mounting table and the shower head and an exhaust space below the substrate mounting table, and the heater is connected with an external power supply via a power supply line penetrating the exhaust plate.

15. The substrate processing apparatus of claim 9, wherein the heater is provided to be movable in a vertical direction along an inner wall surface of the processing chamber.

16. The substrate processing apparatus of claim 10, wherein the heater is provided to be movable in a vertical direction along an inner wall surface of the processing chamber.

17. The substrate processing apparatus of claim 1, wherein a portion, facing a member which need not be heated, on a surface of the glass body of the heater is coated with an infrared reflection film.

18. The substrate processing apparatus of claim 1, wherein the infrared radiator includes a bundle of carbon wires.

19. The substrate processing apparatus of claim 1, wherein the infrared radiator has an emission peak in a wavelength of about 1200 nm.
